(19) United States
(12) Patent Application Publication
(10) Pub. No.: US 2007/0160919 A1
(43) Pub. Date: Jul. 12, 2007

(54) Phase-Shift Mask Providing Balanced Light Intensity Through Different Phase-Shift Apertures And Method For Forming Such Phase-Shift Mask

(76) Inventors: Gong Chen, Austin, TX (US); Franklin D. Kalk, Austin, TX (US)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 11/690,382

(22) Filed: Mar. 23, 2007

Related U.S. Application Data
(63) Continuation of application No. PCT/US05/34785, filed on Sep. 26, 2005.
(60) Provisional application No. 60/613,343, filed on Sep. 27, 2004.

(51) Int. Cl. G03C 5/00; G03F 1/00

(52) U.S. Cl. 430/5; 430/311; 430/312; 430/322

(57) ABSTRACT

A photomask may include a patterned layer, a phase-shift layer adjacent the patterned layer, a first aperture, a second aperture, and a light-absorbing layer. The first aperture may allow light to pass through the patterned layer and the phase-shift layer and provide a first phase shift. The second aperture may allow light to pass through the patterned layer and the phase-shift layer and provide a second phase shift different than the first phase-shift. The light-absorbing layer may be disposed adjacent the first aperture and may include a light-absorbing material that reduces the intensity of light passing through the first aperture such that the intensity of light passing through the first aperture is substantially equal to the intensity of light passing through the second aperture.

### CROSS REFERENCE TO RELATED APPLICATION

This application claims priority from U.S. Provisional Patent Application Ser. No. 60/613,343, filed Sep. 26, 2005, by Gong Chen et al., and entitled “Phase-Shift Mask Providing Balanced Light Intensity Through Different Phase-Shift Apertures And Method For Forming Such Phase-Shift Mask” which is hereby incorporated in its entirety by reference.

### TECHNICAL FIELD OF THE INVENTION

This invention relates in general to photomasks, and more particularly, to a phase-shift mask providing balanced light intensity through different phase-shift apertures and a method for forming such phase-shift mask

### BACKGROUND OF THE INVENTION

In a typical alternating-aperture phase-shift mask (AAPSM), because a 180-degree aperture is associated with an etched-quartz structure, the intensity of light transmitted through a 180-degree aperture is usually less than the intensity of light transmitted through a 0-degree aperture. As a result, a resist line printed on a semiconductor wafer using the photomask may be larger, and the spacing may be smaller, than the designed sizes for the resist line and the spacing. Thus, balancing the intensity of light transmitted through 0-degree apertures and 180-degree apertures in a phase-shift mask during a photolithography process is a practical problem in the application of phase-shift technology. For example, such imbalanced light intensity is problematic in the application of AAPSM for patterning wafers with sub-90 nm node wafer process technologies in semiconductor manufacturing.

Various techniques have been attempted to balance the intensity of light transmitted through 0-degree apertures and 180-degree apertures in phase-shift masks. One common technique involves increasing the size of the 180-degree apertures to increase the intensity of light transmitted through such 180-degree apertures. This technique requires a data-bias step prior to patterning the chromium layer (e.g., patterned layer) of the photomask, and altering the Cr-critical dimension target corresponding to the amount of data bias (for example, by reducing the width of a Cr line in the patterned layer). However, as the design circuit becomes complex (for example, the addition of optical proximity correction (OPC) and sub-resolution assist feature (SRAF) geometries), the data-bias process becomes very difficult, which may cause processing problems.

Another common technique for attempting to balance the intensity of light transmitted through 0-degree apertures and 180-degree apertures in phase-shift masks involves performing a wet-etch to remove portions of the quartz substrate under the patterned layer to increase the size of the trenches associated with the 180-degree apertures, thus increasing the intensity of light transmitted through such 180-degree apertures. However, etching portions of the substrate below the patterned layer may result in over-hanging portions of the patterned layer, which may break off during various processes, such as aggressive cleaning processes, thus causing an un-repairable defect in the photomask. In addition, in applications using a thin patterned layer, such as a sub-300 nm patterned layer used for sub-75 nm node design, the patterned layer may easily peal, resulting in a defective photomask.

### SUMMARY OF THE INVENTION

In accordance with teachings of the present invention, disadvantages and problems associated with forming phase-shift photomasks providing balanced light intensity through phase-shift apertures of different degrees have been substantially reduced or eliminated. In a particular embodiment, a thin light-absorbing layer may be disposed over 0-degree phase shift apertures to reduce the intensity of light transmitted through the 0-degree phase shift apertures in order to balance the light intensity of the 0-degree phase shift apertures with 180-degree phase shift apertures in the same photomask.

According to one embodiment, a photomask may include a patterned layer, a phase-shift layer adjacent the patterned layer, a first aperture, a second aperture, and a light-absorbing layer. The first aperture allows light to pass through the patterned layer and the phase-shift layer and provides a first phase shift. The second aperture allows light to pass through the patterned layer and the phase-shift layer and provides a second phase shift different than the first phase-shift. The light-absorbing layer may be disposed adjacent the first aperture and includes a light-absorbing material that reduces the intensity of light passing through the first aperture such that the intensity of light passing through the first aperture is substantially equal to the intensity of light passing through the second aperture.

According to another embodiment, a method for forming a photomask that provides substantially balanced light intensity through different phase-shift apertures is provided. A photomask structure is provided that may include a patterned layer, a phase-shift layer adjacent the patterned layer, a first aperture that allows light to pass through the patterned layer and the phase-shift layer and provides a first phase shift, and a second aperture that allows light to pass through the patterned layer and the phase-shift layer and provides a second phase shift different than the first phase-shift. A light-absorbing layer may be formed adjacent the first aperture. The light-absorbing layer may include light-absorbing material that reduces the intensity of light passing through the first aperture such that the intensity of light passing through the first aperture is substantially equal to the intensity of light passing through the second aperture.

According to yet another embodiment, another method for forming a photomask that provides substantially balanced light intensity through different phase-shift apertures is provided. A photomask structure is formed that may include a patterned layer and a phase-shift layer adjacent the patterned layer. The patterned layer may include a first opening exposing a first portion of the phase-shift layer and a second opening exposing a second portion of the phase-shift layer. A light-absorbing layer may be formed adjacent the patterned layer and extends into the first and second openings in the patterned layer such that a first portion of the light-absorbing layer covers the first exposed portion of the phase-shift layer and a second portion of the light-absorbing layer covers the second exposed portion of the phase-shift layer. A resist layer may be formed adjacent the first portion of the light-absorbing layer covering the first exposed portion of the light-absorbing layer, but not adjacent the second portion of the light-absorbing layer covering the second exposed portion of the phase-shift layer. An etching process may be performed through the resist layer such that the second portion of the light-absorbing layer, but not the first portion of the light-absorbing layer, is removed. The resist layer may then be removed.

The resulting photomask structure may include a first aperture corresponding with the first opening in the patterned layer and a second aperture corresponding with the second opening in the patterned layer. The first and second apertures may provide different degrees of phase-shift for incident light. The first portion of the light-absorbing layer may reduce the intensity of light passing through the first aperture such that the intensity of light passing through the first aperture is substantially equal to the intensity of light passing through the second aperture.

The present invention may provide various technical advantages. For example, using a light-absorbing layer to absorb a portion of light transmitted through particular apertures (e.g., 0-degree apertures) in a phase-shift mask in order to balance the intensity of light transmitted through various apertures in the mask may provide various advantages of other attempted techniques for balancing light intensity.

For example, in contrast to some prior techniques for balancing light intensity that involve a data-bias step prior to forming the pattern in the patterned layer of the photomask in order to increase the light intensity through a 180-degree aperture, the present invention may require no data-bias prior to writing the pattern in the patterned layer of the photomask. Thus, the present invention may facilitate the process of writing the pattern in the patterned layer and/or associated metrology processes. In addition, the OPC design may be preserved without an extra data-bias step.

As another example, in contrast to some prior techniques for balancing light intensity that involve a wet-etch of the substrate under portions of the patterned layer of the photomask in order to increase the light intensity through a 180-degree aperture, the present invention may require no etching of the substrate below the patterned layer. As a result, overhanging portions of the patterned layer may be reduced or eliminated, which may be particularly advantageous for small size features in the patterned layer, such as small sized features used for 65 nm node design, for example.

All, some, or none of these technical advantages may be present in various embodiments of the present invention. Other technical advantages will be readily apparent to one skilled in the art from the following figures, descriptions, and claims.

### BRIEF DESCRIPTION OF THE DRAWINGS

A more complete and thorough understanding of the present embodiments and advantages thereof may be acquired by referring to the following description taken in conjunction with the accompanying drawings, in which like reference numbers indicate like features, and wherein:

FIG. 1 illustrates a cross-sectional view of a photomask assembly according to an embodiment of the present invention;

FIG. 2 is an example graph illustrating the intensity of light transmitted through 0-degree and 180-degree apertures of the photomask of FIG. 1, as compared to the intensity of light transmitted through 0-degree and 180-degree apertures of a photomask formed according to prior techniques; and

FIGS. 3A-3E illustrate a method of fabricating a photomask that may provide balanced light intensity through 0-degree phase-shift apertures and 180-degree phase-shift apertures in accordance with one embodiment of the present invention.

### DETAILED DESCRIPTION OF THE INVENTION

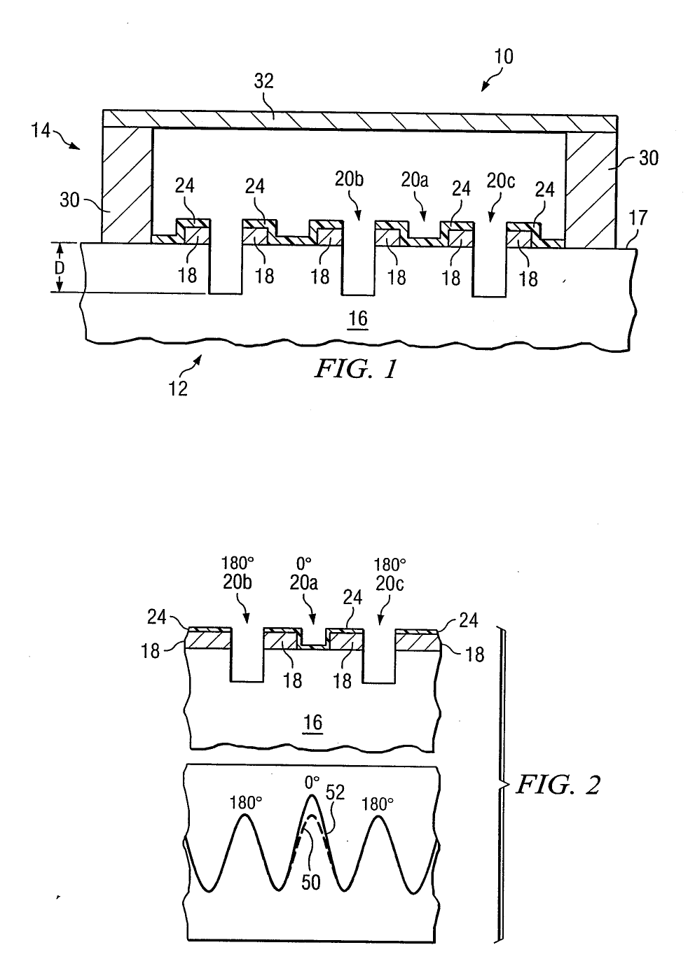

Preferred embodiments of the present invention and their advantages are best understood by reference to FIGS. 1 through 3E, where like numbers are used to indicate like and corresponding parts.

FIG. 1 illustrates a cross-sectional view of an example photomask assembly 10 according to certain embodiments of the invention. Photomask assembly 10 may include a pellicle assembly 14 mounted on a photomask 12. A substrate 16 and a patterned layer 18 may form photomask 12, otherwise known as a mask or reticle, which may have any of a variety of sizes and shapes, including, but not limited to, round, rectangular, or square, for example. Photomask 12 may also be any variety of photomask types, including, but not limited to, a one-time master, a five-inch reticle, a six-inch reticle, a nine-inch reticle, or any other appropriately sized reticle that may be used to project an image of a circuit pattern onto a semiconductor wafer. Photomask 12 may be a phase shift mask (PSM), such as, for example, an alternating-aperture phase-shift mask (AAPSM), also known as a Levenson type mask, or may be any other type of mask suitable for use in a lithography system.

Photomask 12 may include patterned layer 18 formed on a top surface 17 of substrate 16 that, when exposed to electromagnetic energy in a lithography system, projects a pattern onto a surface of a semiconductor wafer. Substrate 16 may be formed from transparent material such as quartz, synthetic quartz, fused silica, magnesium fluoride (MgF₂), calcium fluoride (CaF₂), for example. In some embodiments, substrate 16 may be formed from any suitable material that transmits at least 75% of incident light having a wavelength between approximately 10 nm and approximately 450 nm. In alternative embodiments, substrate 16 may be a reflective material, such as silicon or any other suitable material that reflects greater than approximately 50% of incident light having a wavelength between approximately 10 nm and 450 nm.

Patterned layer 18 may be a metal material such as chrome, chromium nitride, a metallic oxy-carbo-nitride (e.g., MOCN, where M is selected from the group consisting of chromium, cobalt, iron, zinc, molybdenum, niobium, tantalum, titanium, tungsten, aluminum, magnesium, and silicon), or any other suitable material that absorbs electromagnetic energy with wavelengths in the ultraviolet (UV) range, deep ultraviolet (DUV) range, vacuum ultraviolet (VUV) range and/or extreme ultraviolet range (EUW). In alternative embodiments, patterned layer 18 may be a partially transmissive material, e.g., molybdenum silicide (MoSi), which has a transmissivity of approximately 1% to approximately 300 in the UV, DUV, VWV and EUV ranges.

One or more phase-shift apertures 20 may be formed in photomask 12, each operable to shift the phase of light passing through that aperture 20 a particular amount from 0-180 degrees or 0-360 degrees, for example. Each aperture may include an opening in patterned layer 18 and/or a corresponding opening, or trench, in substrate 16 extending for a particular depth through substrate 16. Where substrate 16 is a phase-shifting material, the depth of the opening, or trench, in substrate 16 may determine the degree of phase-shift for the corresponding aperture 20. In the embodiment shown in FIG. 1, photomask 12 may include 0-degree aperture 20a and 180-degree apertures 20b and 20c. In this example embodiment, 0-degree aperture 20a, which provides a 0-degree phase shift for incident light, may include an opening in patterned layer 18, but no corresponding opening, or trench, in substrate 16. In contrast, each 180-degree aperture 20b and 20c, which provides a 180-degree phase shift for incident light, may include an opening in patterned layer 18 and a corresponding opening, or trench, in substrate 16 extending for a depth D through substrate 16. It should be understood that in other embodiments, different degrees of phase shift may be provided by any other suitable shapes, sizes, and/or combinations of openings or trenches in patterned layer 18 and substrate 16.

One or more light-absorbing layers 24 may be disposed over a portion of patterned layer 18. As shown in FIG. 1, an example light-absorbing layer 24 may extend into 0-degree aperture 20a, but not into 180-degree apertures 20b or 20c. Light absorbing layer 24 may be operable to absorb a portion of light transmitted through 0-degree aperture 20a. Thus, light-absorbing layer 24 may reduce the intensity of light transmitted through 0-degree aperture 20a, in order to substantially match the intensity of light passing through 180-degree apertures 20b or 20c, which may otherwise (e.g., without the presence of light absorbing layer 24) be greater than the intensity of light transmitted through 180-degree aperture 20a. The light intensity may be measured by an AIMS tool, for example.

In other embodiments, instead of using one or more light-absorbing layers 24 to provide substantially matched light intensity passing through different apertures, one or more light-absorbing layers 24 may be use to provide desired intensities of transmitted light that do not substantially match for different apertures. For example, one or more light-absorbing layers 24 may be disposed over portions of patterned layer 18 to provide a first intensity of transmitted light through one or more particular apertures (e.g., one or more 0-degree apertures) and a second, substantially different intensity of transmitted light through one or more other particular apertures (e.g., one or more 180-degree apertures). Thus, relative intensities of light through different apertures (e.g., through phase-shift apertures of different degrees) may be provided as desired.

Light-absorbing layer 24 may comprise any one or more materials operable to absorb a portion of light transmitted through such material(s). In some embodiments, light-absorbing layer 24 may be a thin absorption film formed from one or more metallic or organic materials, e.g., chrome, chromium nitride, a metallic oxy-carbo-nitride (e.g., MOCN, where M is selected from the group consisting of chromium, cobalt, iron, zinc, molybdenum, niobium, tantalum, titanium, tungsten, aluminum, magnesium, and silicon), or any other suitable material that absorbs electromagnetic energy with wavelengths in the ultraviolet (UV) range, deep ultraviolet (DUV) range, vacuum ultraviolet (VUV) range and/or extreme ultraviolet range (EUV), for example. Light-absorbing layer 24 may or may not be formed from the same material(s) as patterned layer 18.

In some embodiments, light-absorbing layer 24 comprises a material that alters the transmission of electromagnetic energy, but causes no phase shift or very little phase shift of the electromagnetic energy. In some embodiments, the material(s) and dimensions of light-absorbing layer 24 are selected such that light-absorbing layer 24 reduces the intensity of transmitted light by an amount between approximately 5% and approximately 10% at the exposed wavelengths. For example, in some embodiments, light-absorbing layer 24 may comprise a metal layer with a thickness in the range of approximately 0.2 nm to 10 nm. In other embodiments, light-absorbing layer 24 is designed such that light-absorbing layer 24 reduces the intensity of transmitted light by other amounts and/or may have a thickness outside of the range of approximately 0.2 nm to 10 nm.

Thus, light-absorbing layer 24 may not have any impact on the performance of defect inspection tools. In embodiments in which light-absorbing layer 24 comprises a metallic film, high-energy E-beam writing tools may be used for subsequent layer overly writing processes.

Matching, or balancing, light intensity transmitted through phase-shift apertures of differing degrees, such as 0-degree aperture 20a and 180-degree apertures 20b and 20c, for example, during lithography processes using photomask 12 may provide various advantages. For example, when photomask 12 is used to transfer the various geometries defined by patterned layer 18 onto a semiconductor wafer, the geometries (e.g., lines and other shapes) actually printed onto the semiconductor wafer may more closely approximate the designed, or desired, geometries as compared with using a photomask that transmits imbalanced light intensity through phase-shift apertures of differing degrees.

In addition, balancing the intensity of light transmitted through a phase-shift photomask in the manner described herein may provide various advantages over other attempted techniques for balancing light intensity. For example, in contrast to some prior techniques for balancing light intensity that involve a data-bias step prior to forming the pattern in the patterned layer of the photomask in order to increase the light intensity through a 180-degree aperture, the present techniques may require no data-bias prior to writing the pattern in patterned layer 18. Thus, the techniques discussed herein may facilitate the process of writing the pattern in patterned layer 18, and associated metrology process(es). In addition, the OPC design may be preserved without an extra data-bias step.

As another example, in contrast to some prior techniques for balancing light intensity that involve a wet-etch of the substrate under portions of the patterned layer of the photomask in order to increase the light intensity through a 180-degree aperture, the present techniques may require no etching of substrate 16 below patterned layer 18. As a result, overhanging portions of patterned layer 18 may be reduced or eliminated, which may be particularly advantageous for small size features in patterned layer 18, such as small sized features used for 65 nm node design.

Pellicle assembly 12 may include a frame 30 and a pellicle film 32. Frame 30 may be typically formed of anodized aluminum, but may alternatively be formed of stainless steel, plastic or other suitable materials that do not degrade or outgas when exposed to electromagnetic energy within a lithography system. Pellicle film 32 may be a thin film membrane formed of a material such as nitrocellulose, fluoropolymer, cellulose acetate, an amorphous such as TEFLON® AF manufactured by E. I. du Pont de Nemours and Company or CYTOP® manufactured by Asahi Glass, or another suitable film that is transparent to wavelengths in the V, DUV, EUV and/or VUV ranges, for example. Pellicle film 32 may be prepared by a conventional technique such as spin casting.

Pellicle film 32 may protect photomask 12 from contaminants, such as dust particles, by ensuring that the contaminants remain a defined distance away from photomask 12. This may be especially important in a lithography system. During a lithography process, photomask assembly 10 may be exposed to electromagnetic energy produced by a radiant energy source within the lithography system. The electromagnetic energy may include light of various wavelengths such as wavelengths approximately between the I-line and G-line of a Mercury arc lamp, or DUV, VUV or EUV light, for example. In operation, pellicle film 32 may be designed to allow a large percentage of the electromagnetic energy to pass through it. Contaminants collected on pellicle film 32 will likely be out of focus at the surface of the wafer being processed and, therefore, the exposed image on the wafer should be clear. Pellicle film 32 formed in accordance with the teachings of the present invention may be satisfactorily used with all types of electromagnetic energy and is not limited to lightwaves as described in this application.

Photomask 12 may be formed from a photomask blank using standard lithography processes. In a lithography process, a mask pattern file that may include data for patterned layer 18 may be generated from a mask layout file. In one embodiment, the mask layout file may include polygons that represent transistors and electrical connections for an integrated circuit. The polygons in the mask layout file may further represent different layers of the integrated circuit when it is fabricated on a semiconductor wafer. For example, a transistor may be formed on a semiconductor wafer with a diffusion layer and a polysilicon layer. The mask layout file, therefore, may include one or more polygons drawn on the diffusion layer and one or more polygons drawn on the polysilicon layer. The polygons for each layer may be converted into a mask pattern file that represents one layer of the integrated circuit. Each mask pattern file may be used to generate a photomask for the specific layer. In some embodiments, the mask pattern file may include more than one layer of the integrated circuit such that a photomask may be used to image features from more than one layer onto the surface of a semiconductor wafer.

The desired pattern may be imaged into a resist layer of the photomask blank using a laser, electron beam or X-ray lithography system. In one embodiment, a laser lithography system uses an Argon-Ion laser that emits light having a wavelength of approximately 364 nanometers (nm). In alternative embodiments, the laser lithography system uses lasers emitting light at wavelengths from approximately 150 nm to approximately 300 nm. Photomask 12 may be fabricated by developing and etching exposed areas of the resist layer to create a pattern, etching the portions of patterned layer 18 not covered by resist, and removing the undeveloped resist to create patterned layer 18 over substrate 16.

FIG. 2 is an example graph illustrating plot 50 of the intensity of light transmitted through 0-degree aperture 20a and 180-degree apertures 20b and 20c of photomask 12, as compared to plot 52 of the intensity of light transmitted through a similar photomask formed without light-absorbing layer 24. As indicated by plot 52, the intensity of light transmitted through 0-degree and 180-degree apertures of a photomask similar to photomask 12 (but without light-absorbing layer 24) may be greater through the 0-degree aperture than through the 180-degree apertures. In contrast, as indicated by plot 50, the intensity of light transmitted through 0-degree aperture 20a and 180-degree apertures 20b and 20c of photomask 12 may be substantially equal, or balanced.

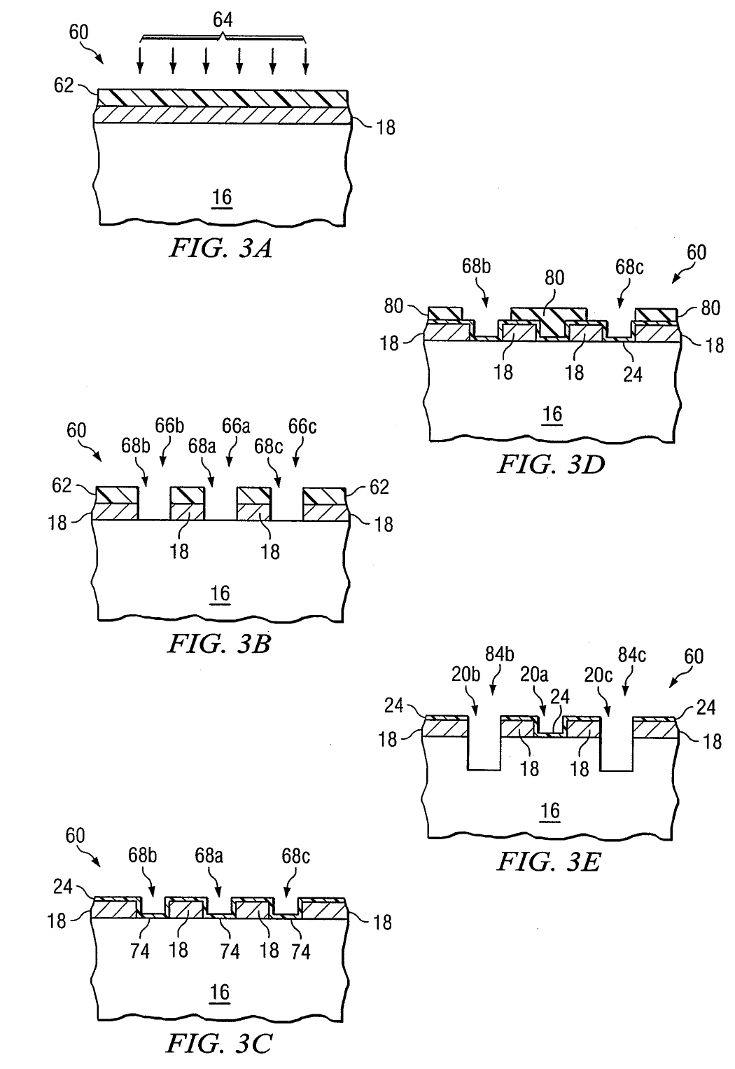

FIGS. 3A-3E illustrate a method of fabricating photomask 12 providing balanced light intensity through 0-degree phase-shift aperture 20a and 180-degree phase-shift apertures 20b and 20c in accordance with one embodiment of the invention. As shown in FIG. 3A, a photomask structure 60 may be formed by depositing patterned layer 18 adjacent substrate 16, and further depositing a resist layer 62 adjacent patterned layer 18. A photolithographic process, such as an E-beam or laser beam process, may be used to transfer a desired pattern onto resist layer 62, as indicated by arrows 64.

As shown in FIG. 3B, resist layer 62 may then be developed to remove portions 66a, 66b and 66c of resist layer 62 exposed by the photolithographic process indicated at 64. An etch process may then be performed through the removed portions 66a, 66b and 66c of resist layer 62 to form trenches 68a, 68b and 68c in patterned layer 18. Resist layer 62 may then be removed.

As shown in FIG. 3C, light-absorbing layer 24 may be deposited adjacent patterned layer 18 such that it extends into trenches 68a, 68b and 68c of patterned layer 18, such that a top surface 74 of each trench 68a, 68b and 68c may be covered by light-absorbing layer 24. Light-absorbing layer 24 may be deposited in any suitable manner, e.g., by physical vapor deposition (e.g., sputtering or vacuum evaporation), chemical vapor deposition, or spin-coating (such as where an organic light-absorbing layer 24 is used, for example).

As shown in FIG. 3D, a resist layer 80 may be formed adjacent, or over, light-absorbing layer 24. Portions of resist layer 80 adjacent trenches 68b and 68c may be exposed, developed, and removed using a standard photolithographic process, such as described above with reference to FIGS. 3A-3C, for example. The process may be performed such that the portion of resist layer 80 adjacent, or covering, trench 68a remains partially or fully intact.

As shown in FIG. 3E, one or more etch processes may be performed through the removed portions of resist layer 80, and through trenches 68b and 68c, to form trenches 84b and 84c in substrate 16. In an embodiment in which light-absorbing layer 24 comprises the same material as patterned layer 18, a first etch may be performed to remove portions of light-absorbing layer 24 exposed through the removed portions of resist layer 80 (e.g., portions of resist layer 80 formed on substrate 16 within trenches 68b and 68c), and a second etch may then be performed through the removed portions of resist layer 80, and through trenches 68b and 68c, to form trenches 84b and 84c in substrate 16. In embodiments in which substrate 16 comprises quartz, such second etch may comprise a quartz etch.

In other embodiments, trenches 84b and 84c may be formed in substrate 16 using a single etch process. For example, light-absorbing layer 24 may comprise a material that has an etch-selectivity similar to that of substrate 16, but different than that of patterned layer 18. Thus, a single etch may be performed to (a) remove portions of light-absorbing layer 24 within trenches 68b and 68c and (b) form trenches 84b and 84c in substrate 16, without etching substantially through exposed portions of patterned layer 18. In other embodiments, any other suitable number and/or type(s) or etch (or other) processes may be performed to form trenches 84b and 84c in substrate 16.

After the one or more etch processes to remove portions of light-absorbing layer 24 within trenches 68b and 68c and to form trenches 84b and 84c in substrate 16, the remaining portion of resist layer 80 may be removed, resulting in the photomask structure shown in FIG. 3E, which may include 0-degree aperture 20a and 180-degree apertures 20b and 20c. Due to the etching process discussed above, light-absorbing layer 24 may extend into 0-degree aperture 20a, but not into 180-degree apertures 20b or 20c, in order to provide the desired result of controlling the intensity of light passing through the various apertures.

Although the present invention has been described in detail, it should be understood that various changes, substitutions, and alteration can be made without departing from the spirit and scope of the invention as defined by the appended claims.

What is claimed is:

1. A method for forming a photomask that provides selectively controllable light intensity through different phase-shift apertures, comprising:
providing a photomask structure including a patterned layer, a phase-shift layer adjacent the patterned layer, a first aperture operable to allow light to pass through the patterned layer and the phase-shift layer and to provide a first phase shift, and a second aperture operable to allow light to pass through the patterned layer and the phase-shift layer and to provide a second phase shift different than the first phase-shift; and
forming a light-absorbing layer adjacent the first aperture, the light-absorbing layer comprising light-absorbing material operable to reduce the intensity of light passing through the first aperture. the second aperture.

2.-3. (canceled)

4. The method of claim 1, wherein the light-absorbing layer absorbs between approximately 5% and approximately 10% of incident light.

5. The method of claim 1, wherein the light-absorbing layer has a thickness in the range of approximately 0.2 nm to approximately 10 nm.

6. The method of claim 1, wherein:
the first aperture comprises a 0-degree phase shift aperture; and
the second aperture comprises a 180-degree phase shift aperture.

7. The method of claim 1, wherein the phase-shift layer comprises quartz.

8. The method of claim 1, wherein, at a particular location on the patterned layer:
the phase-shift layer is formed adjacent a first side of the patterned layer; and
the light-absorbing layer is formed adjacent a second side of the patterned layer opposite the first side of the patterned layer.

9. The method of claim 1, wherein the thickness of the light-absorbing layer is predetermined such that the intensity of light passing through the first aperture is substantially equal to the intensity of light passing through the second aperture.

10. The method of claim 1, wherein the thickness of the light-absorbing layer is predetermined such that the intensity of light passing through the first aperture is not substantially equal to, but has a desired relationship with, the intensity of light passing through the second aperture.

11. The method of claim 1, wherein:
the first aperture comprises a first opening in the patterned layer exposing a first surface of the phase-shift layer;
the second aperture comprises a second opening in the patterned layer exposing a second surface of the phase-shift layer; and
the light-absorbing layer is formed adjacent the first surface of the phase-shift layer but not the second surface of the phase-shift layer.

12. A method for forming a photomask that provides substantially balanced light intensity through different phase-shift apertures, comprising:
forming a photomask structure including a patterned layer and a phase-shift layer adjacent the patterned layer, the patterned layer including a first opening exposing a first portion of the phase-shift layer and a second opening exposing a second portion of the phase-shift layer;
forming a light-absorbing layer adjacent the patterned layer and extending into the first and second openings in the patterned layer such that a first portion of the light-absorbing layer covers the first exposed portion of the phase-shift layer and a second portion of the light-absorbing layer covers the second exposed portion of the phase-shift layer;
forming a resist layer adjacent the first portion of the light-absorbing layer covering the first exposed portion of the light-absorbing layer, but not adjacent the second portion of the light-absorbing layer covering the second exposed portion of the phase-shift layer;
performing one or more etching processes through the resist layer such that the second portion of the light-absorbing layer, but not the first portion of the light-absorbing layer, is removed; and
removing the resist layer.

13. The method of claim 12, wherein the resulting structure comprises a first aperture corresponding with the first opening in the patterned layer and a second aperture corresponding with the second opening in the patterned layer, the first and second apertures providing different degrees of phase-shift for incident light, the first portion of the light-absorbing layer operable to reduce the intensity of light passing through the first aperture such that the intensity of light passing through the first aperture is substantially equal to the intensity of light passing through the second aperture.

14.-15. (canceled)

16. The method of claim 12, wherein the light-absorbing layer absorbs between approximately 5% and approximately 10% of incident light.

17. The method of claim 12, wherein the light-absorbing layer has a thickness in the range of approximately 0.2 nm to approximately 10 nm.

18. The method of claim 12, wherein:
the first aperture comprises a 0-degree phase shift aperture; and
the second aperture comprises a 180-degree phase shift aperture.

19. The method of claim 12, wherein the one or more etching processes remove a portion of the phase-shift layer corresponding with the second opening such that the resulting first and second apertures provide different degrees of phase-shift for incident light.

20. A photomask, comprising:
a patterned layer;
a phase-shift layer adjacent the patterned layer;
a first aperture operable to allow light to pass through the patterned layer and the phase-shift layer and to provide a first phase shift;
a second aperture operable to allow light to pass through the patterned layer and the phase-shift layer and to provide a second phase shift different than the first phase-shift; and
a light-absorbing layer disposed adjacent the first aperture, the light-absorbing layer comprising light-absorbing material operable to reduce the intensity of light passing through the first aperture such that the intensity of light passing through the first aperture is substantially equal to the intensity of light passing through the second aperture.

21. The photomask of claim 20, wherein the light-absorbing layer comprises a metallic or organic film.

22. The photomask of claim 20, wherein the light-absorbing layer is formed from the same one or more materials as the patterned layer.

23. The photomask of claim 20, wherein the light-absorbing layer absorbs between approximately 5% and approximately 10% of incident light.

24. The photomask of claim 20, wherein the light-absorbing layer has a thickness in the range of approximately 0.2 nm to approximately 10 nm.

25. The photomask of claim 20, wherein:
the first aperture comprises a 0-degree phase shift aperture; and
the second aperture comprises a 180-degree phase shift aperture.

26. The photomask of claim 20, wherein the phase-shift layer comprises quartz.

27. The photomask of claim 20, wherein, at a particular location on the patterned layer:
the phase-shift layer is located adjacent a first side of the patterned layer; and
the light-absorbing layer is located adjacent a second side of the patterned layer opposite the first side of the patterned layer.

28. The photomask of claim 20, wherein the thickness of the light-absorbing layer is selected such that the intensity of light passing through the first aperture is substantially equal to the intensity of light passing through the second aperture.

29. The photomask of claim 20, wherein the thickness of the light-absorbing layer is selected such that the intensity of light passing through the first aperture is not substantially equal to, but has a desired relationship with, the intensity of light passing through the second aperture.

30. (canceled)
